(19) United States
(12) Patent Application Publication
(10) Pub. No.: US 2022/0149305 A1
(43) Pub. Date: May 12, 2022

(54) Compositions and Methods For Reducing Defects In Perovskite-Oxide Interface

(71) Applicant: Arizona Board of Regents on behalf of the University of Arizona, Tucson, AZ (US)

(72) Inventors: Neal R. Armstrong, Tucson, AZ (US); Richard Clayton Shallcross, Tucson, AZ (US)

(73) Assignee: Arizona Board of Regents on behalf of the University of Arizona, Tucson, AZ (US)

(21) Appl. No.: 17/429,345

(22) PCT Filed: Feb. 9, 2020
(86) PCT No.: PCT/US20/17386

§ 371 Date: Aug. 8, 2021

Related U.S. Application Data
(60) Provisional application No. 62/803,583, filed on Feb. 10, 2019.

(51) Int. Cl. H01L 51/44; H01L 51/10; H01L 51/52; H01G 9/20; H01L 51/00

(52) U.S. Cl. CPC H01L 51/441; H01L 51/105; H01L 51/5237; H01L 51/5206; H01L 51/5221; H01G 9/2027; H01L 2251/308; H01G 9/204; H01L 51/0077; H01L 51/0094; H01L 2251/303; H01L 2251/306; H01G 9/2031

(57) ABSTRACT

The present invention provides compositions comprising a metal oxide electrode, a passivating agent on its surface, and a hybrid organic-inorganic perovskite active layer in contact with the metal oxide electrode surface. The presence of a passivating agent on the metal oxide surface increases stability and/or photovoltaic power conversion efficiency of the electronic component comprising a composition of the invention.

### CROSS-REFERENCE TO RELATED APPLICATIONS

This application claims the priority benefit of U.S. Provisional Application No. 62/803,583, filed Feb. 10, 2019, which is incorporated herein by reference in its entirety.

### STATEMENT REGARDING FEDERALLY FUNDED RESEARCH

This invention was made with government support under grant number 1506504 awarded by NSF. The government has certain rights in the invention.

### FIELD OF THE INVENTION

The present invention relates to compositions useful in electronic devices or in electronic components and methods for producing and using the same. In particular, the present invention relates to a composition comprising a metal oxide electrode, a hybrid organic-inorganic perovskite active layer, and a passivating agent in between the surface of said metal oxide and said hybrid organic-inorganic perovskite active layer. In particular, the surface of metal oxide is coated with a thin layer of said passivating agent prior to introduction of the hybrid organic-inorgancid perovskite active layer. The presence of a passivating agent in between the metal oxide electrode and the hybrid organic-inorganic perovskite active layer increases inter alia the stability and/or photovoltaic power conversion efficiency of the electronic component comprising a composition of the invention.

### BACKGROUND OF THE INVENTION

Thin film photovoltaic (PV) cells incorporating hybrid perovskite active layers (PALs or hybrid organic-inorganic perovskite active layers) and TiO₂ contacts have shown to provide a significant power conversion efficiency. However, previously unexplained reactions between the TiO₂ surface and perovskite precursors lead to the formation of substoichiometric and electron-blocking interface passivation layers, which significantly limit the long-term performance and stability of PV devices.

Hybrid organic/inorganic perovskite active layers (PALs; e.g., methylammonium lead iodide—MAPbI₃) have recently shown extraordinary performance in photovoltaic (PV) devices, enabling power conversion efficiencies (PCE) in excess of 20%. PALs are also of interest in photodetector, light-emitting diode, and laser platforms due to their low material cost, solution-processability, high charge mobility, long carrier diffusion lengths, strong optical absorption, and compositionally-tuned absorption/luminescence. Broader applications of PALs are impeded by knowledge gaps related at least in part to: (1) understanding and improving long-term chemical and structural stability of both the PAL and electrical contacts during exposure to moisture, oxygen, heat and illumination; (2) identifying and suppressing the chemical and physical processes behind current-voltage (J-V) hysteresis; (3) reliably estimating the interfacial and bulk band edge (e.g., valence and conduction band) energies, which govern charge transport, collection and injection; and (4) replacing Pb with a less toxic B-site cation (e.g., Sn).

Differences in PV device performance and stability have been attributed to disparities between the bulk and interfacial chemical composition, morphology and band edge offsets for PALs on prototypical titanium dioxide (TiO₂) electron transport contacts. These critical interface properties and, thus, performance and stability of PV devices can be significantly enhanced (>20% PCE) by addition of costly fullerene interlayers between the TiO₂ contact and vacuum-processed MAPbI₃ active layers; however, the exact role of the oxide surface chemistry and that of the modifier is not understood. While these performance and stability issues have been attributed to inferred chemical reactions and interactions at the hybrid organic-inorganic perovskite and metal electrode (e.g., MAPbI₃/TiO₂) interface, reactions between the hybrid organic-inorganic perovskite precursors and metal electrode substrate during film processing, which lead to the formation of electron-blocking interface passivation layers, have yet to be elucidated.

Therefore, there is a need to understand the interaction between the hybrid organic-inorganic perovskite and metal electrode interface in order to overcome or reduce the interfacial defects resulting in a significantly increased performance and/or stability as well as possibly reducing hysteresis of electronic components that utilize PALs.

### SUMMARY OF THE INVENTION

Some aspects of the present invention are based at least in part on elucidation of the mechanism associated with interaction on the interfacial layer of between hybrid organic-inorganic perovskite and metal electrode. In particular, the present inventors have discovered that undesirable interactions between the PAL and metal oxide layers at the interface can be mitigated by modifying the metal oxide surface with a passivating agent, e.g., bifunctional silanes. One specific example of the passivating agent that can be used in the present invention include, but is not limited to, (3-aminopropyl)triethoxysilane (APTES). Still in other embodiments, the passivating agent forms a self-assembling monolayer (SAM) within the interface.

Without being bound by any theory, it is believed that some passivating agents, e.g., bifunctional silane compounds, can form stable covalent bonds with surface hydroxyl groups and coordinate covalent bonds between the free base amine and Lewis acid sites in the metal oxide electrode, such as TiO₂. The present inventors have discovered that these treatments (1) passivate reactive oxide surfaces sites that are believed to be responsible for perovskite degradation, (2) provide uniform vacuum coated films on the perovskite, (3) decrease thickness of undesirable layers near the interface, and/or (4) induce band bending to facilitate charge transport. Application of a passivating agent can be performed using either a vapor-phase or a solution-based coating process, thereby significantly increasing the utility of the present method compared to conventional methods.

Methods of the invention can be extended to applications beyond PV, such as any electrochemical system, light-emitting diode or in general in any and all electrochromic devices incorporating perovskite structures that are interfaced with a metal oxide.

One particular aspect of the invention provides a composition comprising: (i) a thin film metal oxide electrode (e.g., electrical contact), (ii) a passivating agent added to the surface of the metal oxide, (iii) the surface-modified metal oxide electrode in contact with a hybrid organic-inorganic perovskite active layer. In some embodiments, the passivating agent is covalently bonded to the metal oxide electrode surface. Yet in other embodiments, the composition is used in a solar cell device (e.g., photovoltaic) configuration.

In some embodiments, the metal oxide passivating agent comprises a multifunctional silane. Typically, the passivating agent is a bifunctional silane.

Another aspect of the invention is directed to an electronic device comprising a composition described herein. Generally, the metal oxide is used as a charge collection or a charge injection electrode, such as in a photovoltaic cell, a light-emitting diode, or a field-effect transistor.

Yet another aspect of the invention provides a method for increasing stability and/or photovoltaic power conversion efficiency in an electronic component composition comprising a hybrid perovskite layer and a metal oxide electrode. The method includes:
passivating a defect on a surface of said metal oxide layer with a passivating agent; and
contacting said passivated surface of said metal oxide with a perovskite precursor to form said electronic component having a passivation layer between said metal oxide layer and said hybrid perovskite layer,
   where the presence of said passivation layer increases stability and/or photovoltaic power conversion efficiency of said electronic component compared to the same electronic component in the absence of said passivation layer.

Still another aspect of the invention provides a method for reducing hysteresis in an electronic component that includes a hybrid perovskite layer and a metal oxide layer. In this aspect of the invention, the method includes:
passivating a defect on a surface of said metal oxide layer with a passivating agent; and
contacting said passivated surface of said metal oxide with a perovskite precursor to form said electronic component having a compositionally-tuned passivation layer between said metal oxide layer and said hybrid perovskite layer,
   where the presence of said passivation layer decreases hysteresis and, thus, improves the long-term stability of said electronic component compared to the same electronic component in the absence of said passivation layer.

### DETAILED DESCRIPTION OF THE INVENTION

Some aspects of the invention are based on analysis and discovery of interfacial region interaction between the metal oxide electrode (e.g., TiO₂) and hybrid organic-inorganic perovskite (e.g., MAPBI₃). In particular, the present inventors have investigated the role of TiO₂ surface chemistry on the chemical composition and electronic structure of MAPbI₃ films during stepwise co-deposition of methylammonium iodide (MAI) and PbI₂ using X-ray photoelectron spectroscopy (XPS) and ultraviolet photoelectron spectroscopy (UPS).

In particular, a molecular-level experimental investigation of the interfacial interactions and reactions that control chemical and electronic equilibration between pristine and aminosilane-functionalized TiO₂ electron-collecting contacts and vacuum deposited MAPbI₃ perovskite active layers showed that treatment of metal oxide surface with a passivating agent prior to addition of hybrid organic-inorganic perovskite significantly increases stability and/or photovoltaic power conversion efficiency. Furthermore, adding a passivating agent in between the metal oxide electrode and the hybrid organic-inorganic perovskite reduces hysteresis in an electronic component comprising such a composition.

In order to probe the chemical interactions and reactions at the TiO₂/MAPbI₃ interface, along with the evolution of the band edge energies of the MAPbI₃ film and buried TiO₂ contact, MAPbI₃ films were incrementally co-evaporated from methylammonium iodide and PbI₂ precursors, and the near-surface chemical composition and electronic structure was investigated using in situ photoelectron spectroscopy (XPS/UPS). Downward shifts in the core level (e.g., Ti 2p_{3/2}) binding energies of the buried TiO₂ contact and differences in attenuation of two unique hydroxyl groups on the TiO₂ surface during MAPbI₃ film growth indicated that Fermi level equilibration between MAPbI₃ and TiO₂ is achieved by combinations of surface-catalyzed dissociation and proton- and oxygen-coupled redox reactions, which are driven by equilibration of the near-surface and bulk energetics of the TiO₂ contact.

Without being bound by any theory, it is believed that these interactions and reactions strongly influence thin film growth, MAPbI₃ nucleation, and composition near the TiO₂/MAPbI₃ interface and result in an interface passivation layer with variable composition and thickness that depends on the TiO₂ surface composition. Using a metal oxide electrode surface passivating agent, such as silane compounds (e.g., aminosilanes), significantly reduces the amount of strongly-interacting Ti Lewis acid and reactive hydroxyl Brønsted acid/base sites on the TiO₂ surface and result in thinner interface passivation layers with improved physical properties. The interfacial and bulk energetics, which are estimated from deconvoluted UPS valence band spectra using a novel protocol based on Gaussian interpolation, indicate that compositionally-graded and thin passivation layers formed on aminosilane-functionalized TiO₂ contacts improve electronic coupling at the TiO₂/MAPbI₃ interface, promote band bending and mitigate interface dipoles. Overall, these results indicate that the performance and stability of hybrid perovskite PV devices can be enhanced by relatively simple and scalable chemical modification strategies that passivate hydroxyl and Ti defects on TiO₂ electron collecting contacts.

Precursor/MAPbI₃ film growth is island-like on the bare TiO₂ surface, and nucleation of the stoichiometric perovskite phase is not reached until ca. 15 nm, which defines the thickness of the passivation layer. In contrast, it was observed that film growth was conformal and nucleation of MAPbI₃ occurred after ca. 5-8 nm on TiO₂ contacts modified with cost-efficient and scalable passivating agent (3-aminopropyl)triethoxysilane (APTES) self-assembled monolayers (SAMs), where the relative APTES coverage and degree of protonation was tailored by subsequent treatment in dilute HCl and KOH solutions. Sample-dependent variations in the chemical composition and energetics of the buried TiO₂ contact and passivation/MAPbI₃ layer indicated that chemical bonds between APTES molecules and reactive TiO₂ surface sites suppress coupled surface-catalyzed dissociation and redox reactions with MAI-related species, drastically improving interfacial energetics for charge extraction and transport. The molecular-level insights gained from this investigation resulted in the present invention where surface modification strategies that optimize the interfacial chemical composition and energetics of PALs for enhanced performance and long-term stability of devices.

In fact, it has been found by the present inventors, that any bifunctional silanes can be used to enhance the performance and long-term stability of PALs. As used herein, a bifunctional silane refers to a silane compound having two functional groups. One of the functional groups can be used to attach the silane compound to the surface of metal oxide electrode, such as TiO₂, and the other functional group can be used to attach hybrid organic-inorganic perovskite.

In particular, one aspect of the invention provides a composition comprising: (i) a metal oxide electrode (i.e., electrical contact) and (ii) a hybrid organic-inorganic perovskite active layer. The composition includes a passivating agent in between the metal oxide electrode (i) and the hybrid organic-inorganic perovskite (ii). The passivating agent (e.g., a silane compound) is typically covalently bonded to the metal oxide electrode surface, thereby passivating the metal oxide electrode surface prior to adding a layer of hybrid organic-inorganic perovskite. The composition of the invention can be used in a wide variety of electronic components such as, but not limited to, in a solar cell device or a photovoltaic device.

Without being bound by any theory, it is believed that the passivating agent reduces the number of reactive functional group (e.g., hydroxyl group) that is present on the surface of the metal oxide electrode, thereby reducing the problems associated with conventional electrodes or same electrodes without the presence of the passivating agent. In one particular embodiment, the passivating agent is a bifunctional silane compound.

Yet in other embodiments, the passivating agent is of the formula: ARB, where A is a silane functional group (e.g., —Si(OR^{a})ₘXₙ, where m and n are integers such that m+n is 3, each R^{a} is independently H or C₁₋₂₀ alkyl, and X is halide, e.g., chloride, bromide, iodide or fluoride), R is a linker having from about 3 to 20 atoms in a chain between A and B; and B comprises an amino group, mercapto, halide (e.g., fluoride, chloride, bromide, or iodide), sulfobetane, carboxybetane, or a combination thereof, or R and B together form optionally substituted para-aminophenyl or pyridine. When the passivating agent is added to a metal oxide, the silane group of the passivating agent becomes bonded to the reactive hydroxide group of the metal oxide. In this manner, the hydroxide group becomes part of the silane group, thereby rendering the reactive hydroxide group unreactive silane group.

In one particular embodiment, A is of the formula (R¹)₃—Si—, where each of R¹ is independently selected from the group consisting of hydroxyl, alkoxide or halide. Yet in other embodiments, B comprises: —NR^{a}₂, —NR^{a}—[C₁₋₆ alkylene]-NR^{a}₂, —SH, —X, —N⁺(R^{a})₂—[C₁₋₆ alkylene]-SO₃⁻, or —N⁺(R^{z})₂—[C₁₋₆ alkylene]-CO₂⁻, where each R^{z} is independently hydrogen or C₁₋₁₀ alkyl; and X is halide. As used herein, “alkyl” refers a saturated linear monovalent hydrocarbon moiety typically comprising one to twelve and often one to six carbon atoms or a saturated branched monovalent hydrocarbon moiety typically comprising three to twelve and often three to six carbon atoms. Exemplary alkyl group include, but are not limited to, methyl, ethyl, n-propyl, 2-propyl, tert-butyl, pentyl, and the like. The term “alkylene” refers to a saturated linear divalent hydrocarbon moiety typically one to twelve and often one to six, carbon atoms or a branched saturated divalent hydrocarbon moiety typically comprising three to twelve and often three to six carbon atoms. Exemplary alkylene groups include, but are not limited to, methylene, ethylene, propylene, butylene, pentylene, and the like. The term “alkoxide” refers to a moiety of the formula —OR^{x} where R^{x} is alkyl as defined herein.

In some particular embodiments, the passivating agent is selected from the group consisting of a compound of the formula:

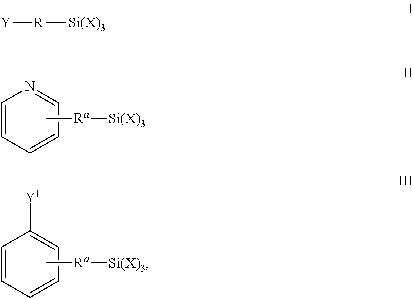

and a mixture thereof where

Y and Y¹ is —NR¹R², —SH, halide, or

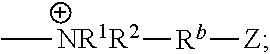

each of R¹ and R² is independently H or C₁₋₁₀ alkyl;

R^{a} is absent or C₁₋₁₀ alkylene, typically C₁₋₆, and often C₂₋₄ alkylene;

R^{b} is C₂₋₁₀ alkylene, often C₂₋₄ alkylene;

each X is independently halide or —OR¹; and

Z is —SO₃⁻or —CO₂.

In one particular embodiment, the passivating agent is a compound of Formula I:

Y—R—Si(X)₃

where Y, R and X are those defined herein. Within this embodiment, R is typically C₂₋₆ alkylene, often C₂₋₄ alkylene, and most often propylene. In some instances, each X is independently halide (such as chloride, bromide, iodide, or fluoride; typically, halide is chloride) or —OR¹, where R¹ is typically C₁₋₆ alkyl, often C₁₋₄ alkyl, more often C₁₋₃ alkyl, and most often methyl or ethyl. In some embodiments, Y is —NR¹R². In one particular embodiment, Y is —NH₂.

Yet in another embodiment, the passivating agent is a compound of Formula II:

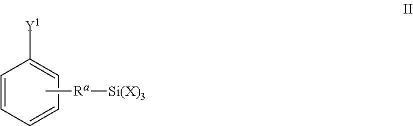

where Y¹, R^{a}, and X are those defined herein. Within this embodiment, in some instances Y¹ is attached in the para-position relative to —R^{a}—Si(X)₃. However, it should be appreciated that the scope of the invention is not limited to having Y¹ attached to the para-position. It can be attached to ortho- or meta-position relative to —R^{a}—Si(X)₃. In some instance, each X is independently halide (typically chloride) or —OR¹, where R¹ is typically H or C₁₋₆ alkyl, often C₁₋₄ alkyl, more often C₁₋₃ alkyl, and most often methyl or ethyl. In some embodiments, Y¹ is —NR¹R². In one particular embodiment, Y¹ is —NH₂. In one particular embodiment, R^{a} is absent such that —Si(X)₃ is attached directly to the phenyl ring system.

Still in another embodiments, the passivating agent is a compound of Formula III:

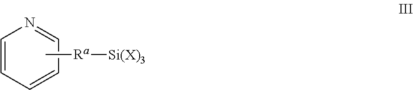

where R^{a} and X are those defined herein. Within this embodiment, in some instances the substituent —R^{a}—Si(X)₃ is in the para-position (i.e., 4-position) relative to the nitrogen atom of the pyridine ring. However, it should be appreciated that the scope of the invention is not limited to the substituent in the para-position relative to the nitrogen atom of the pyridine ring. The substituent can also be attached to ortho- or meta-position relative to the pyridine ring's nitrogen atom. In some instance, each X is independently halide (typically chloride) or OW, where R¹ is typically C₁₋₆ alkyl, often C₁₋₄ alkyl, more often C₁₋₃ alkyl, and most often methyl or ethyl. In one particular embodiment, R^{a} is absent such that —Si(X)₃ is attached directly to the pyridine ring system.

In general, any metal oxide that is used in electronic component can be used in the present invention. Such metal oxides are well known to one skilled in the art and include, but are not limited to, titanium oxide (TiO₂), indium-tin oxide (ITO, also known as tin-doped indium oxide), tin oxide (SnO₂), nickel oxide (NiO), zinc oxide (ZnO), aluminum-doped zinc oxide (AZO), indium-zinc oxide (IZO), and ternary and quaternary metal oxides commonly used as electrical contacts, such as zinc-tin-indium oxide (ZITO), and gallium-zinc-indium oxide (GIZO).

With regards to hybrid perovskites, there are many hybrid perovskites known to one skilled in the art. And the scope of the invention is not limited to any particular hybrid perovskites. Exemplary hybrid perovskites that can be used in the present invention include, but are not limited to, methylammonium lead or tin trihalide, formamidinium lead or tin trihalide, cesium lead or tin trihalide, combinations of lead (or tin) as the central metal cation, and additional cations including cesium, rubidium, bismuth, methylamine, ethylamine, formamidinium-amine and related singly charged metal and organic cations. It should be noted that other hybrid perovskites that are currently being developed or will be developed can also be used in the present invention.

Yet another aspect of the invention provides an electronic device comprising a composition disclosed herein, namely a metal oxide having a passivating agent on its surface and a hybrid perovskite attached thereto. In some embodiments, the composition of the invention is used in an electronic device as a charge collection or a charge injection electrode. Exemplary electronic devices or components that are used in charge collection or charge injection electrode include a photovoltaic cell, a light-emitting diode, and a field-effect transistor.

It has been discovered by the present inventors that by including or adding a passivating agent in between the metal oxide layer and the hybrid perovskite layer, the stability and/or photovoltaic power conversion efficiency in an electronic component composition is significantly increased compared to the same electronic component in the absence of said passivation layer. In some embodiments, the stability of an electronic composition of the present invention is increased by at least about 10%, typically at least about 20%, and often at least about 50%, compared to the same electronic component in the absence of the passivating agent as measured by the half-life of the electronic component. The terms “about” and “approximately” when referring to a numeric value are used interchangeably herein and refer to a value being within an acceptable error range for the particular value as determined by one of ordinary skill in the art, which will depend in part on how the value is measured or determined, i.e., the limitations of the measurement system or the degree of precision required for a particular purpose. For example, the term “about” can mean within 1 or more, typically within 1, standard deviation, per the practice in the art. Alternatively, the term “about” when referring to a numerical value can mean±20%, typically ±10%, often ±5% and more often ±1% of the numerical value. In general, however, where particular values are described in the application and claims, unless otherwise stated, the term “about” means within an acceptable error range for the particular value.

In some embodiments, the photovoltaic power conversion efficiency in the electronic component comprising a passivating agent is increased by at least about 5%, typically at least about 10%, and often at least about 25%, compared to the same electronic component in the absence of the passivating agent.

Without being bound by any theory, it is believed that by adding a passivating agent, the amount of defects and/or the number of reactive functional groups on the surface of the metal oxide layer is significantly reduced. In some embodiments, the amount of defects and/or the number of reactive functional groups on the surface of the metal oxide layer is reduced by at least about 10%, typically by at least about 25%, and often by at least about 50%.

The method of the invention typically includes passivating or reducing the number of reactive functional group and/or the defect on a surface of the metal oxide layer with a passivating agent. This passivated surface is than contacted with or coated or covered with a perovskite precursor to form the electronic component having a passivation layer between the metal oxide layer and the hybrid perovskite layer. As noted, the hybrid perovskite layer can be formed on top of the passivated layer by adding a suitable precursor to the passivated metal oxide surface and allowing formation of the hybrid perovskite.

In one particular embodiment, the passivating agent is formed as a self-assembled monolayer. Typically, the silane group is attached or covalently bonded to the metal oxide surface, and a second functional group or the tail-end functional group of the passivating agent is attached to the hybrid perovskite layer. This provides bonding of the passivating agent to both the metal oxide and the hybrid perovskite. Such formation of bond to both the metal oxide and the perovskite layer prevents detachment of perovskite from the metal oxide layer that is typically observed in conventional metal oxide-hybrid perovskite composition. Again without being bound by any theory, it is believed that this bonding to both the metal oxide and the hybrid perovskite by the passivating agent is at least responsible for the stability and/or photovoltaic power conversion efficiency observed in compositions of the present invention.

In some embodiments, the passivating agent reduces the total number of reactive sites on the surface of the metal oxide layer. These sites can be chemically reactive hydroxyl sites (—OH), which are singly or doubly bonded to the underlying metal cation, or undercoordinated metal cation sites.

Passivation of the metal oxide using a passivating agent as disclosed herein can be achieved in any manner known to one skilled in the art. In one embodiment, the passivation of the metal oxide layer comprises a chemical vapor deposition process in a low humidity environment. Because the silane group can react with water vapor, it is desired a relatively low humidity reaction condition is used. Alternatively, a high concentration of passivating agent can be used to ensure at least some of the passivating agent is reacted with the metal oxide surface. The term “low humidity” refers to a reaction condition having no more than about 50% humidity, typically no more than about 25% humidity, and often no more than about 5% humidity.

In another embodiments, the passivation of the metal oxide layer is conducted using an anhydrous, solution-based process. As used herein, an “anhydrous” refers to a solution having about 1% or less, typically about 0.1% or less, and often about 0.01% or less of water content. Alternatively, the amount of passivating agent used is greater than the total number of water molecule present in the solution. In this manner, one can ensure at least a portion of the metal oxide is passivated.

Yet another aspect of the invention provides a method for reducing hysteresis in an electronic component. This method includes passivating a defect on a surface of a metal oxide layer with a passivating agent; and contacting the passivated metal oxide surface with a perovskite precursor to form an electronic component having a compositionally-tuned passivation layer between the metal oxide layer and the hybrid perovskite layer. The presence of the passivation layer decreases hysteresis and, thus, improves the long-term stability of the electronic component compared to the same electronic component in the absence of the passivation layer.

Additional objects, advantages, and novel features of this invention will become apparent to those skilled in the art upon examination of the following examples thereof, which are not intended to be limiting. In the Examples, procedures that are constructively reduced to practice are described in the present tense, and procedures that have been carried out in the laboratory are set forth in the past tense.

### Examples

General Methods

Materials. Acetone (ACS grade, Fisher Chemical), ethanol (absolute, Decon Labs), toluene (anhydrous, 99.8%, Sigma Aldrich), isopropanol (IPA, ACS Grade, EMD), (3-aminopropyl)triethoxysilane (APTES, 99%, Acros Organics Sure Seal), KOH (ACS Grade, BDH/VWR), HCl (ACS Grade, EMD), nanopure H₂O (18.2 MW·cm using a Milli-Q UV Plus Millipore water purification system), PbI₂ (ultradry, 99.999% metals basis, Alfa Aesar) are used without further purification unless stated otherwise. Methylammonium iodide (MAI) was prepared according to procedure known to one skilled in the art. See, for example, J. Am. Chem. Soc., 2012, 134, 17396-17399.

Preparation of TiO₂ and APTES-modified TiO₂ thin films. Conformal TiO₂ films (ca. 30 nm thick) were deposited onto oxygen plasma treated indium tin oxide (ITO) substrates in a home-built chemical vapor deposition (CVD) system that has been described by the present inventors in Shallcross, R. C. et al., in “Determining Band-Edge Energies and Morphology-Dependent Stability of Formamidinium Lead Perovskite Films Using Spectroelectrochemistry and Photoelectron Spectroscopy,” JACS, 2017, 139, 4866-4878. Titanium(IV) isopropoxide was delivered to heated (210° C.) ITO substrates in an ultra-high purity N₂ carrier gas at a flow rate of 0.66 cm³/min, which corresponds to a deposition rate of ca. 1.2 nm/min. Bare “TiO₂” samples were treated with oxygen plasma (17 W, 800 mTorr, 10 min). APTES was adsorbed from the vapor-phase to TiO₂ samples in a N₂ glovebox (<0.1 ppm H₂O and <1 ppm O₂) using a previously-reported procedure with some modifications. See, for example, Zhu, M. et al., in “How to prepare reproducible, homogeneous, and hydrolytically stable aminosilane-derived layers on silica,” Langmuir 2012, 28, 416-423. APTES was dispensed into a glass crucible that was placed in the center of a jar, and the TiO₂ thin films were placed around the crucible. The threads were wrapped with PTFE tape prior to fixing the lid. The sealed jar was then placed on an 85° C. hotplate for one hour. After removing the APTES-treated films and bringing the samples into ambient, the samples were rinsed with toluene and ethanol, dried with N₂ and transferred back into the N₂ glovebox where they are annealed on a hotplate 120° C. for 5 min. Prior to loading the samples into the ultra-high vacuum (UHV) system, the aminosilane-treated TiO₂ substrates were brought into ambient and dipped into freshly-prepared HCl (50 mM, pH≈1.3) or KOH (10 mM, pH≈12.0) solutions for 15 s and dried with a stream of N₂ to yield “APTES-HCl” or “APTES-KOH” samples, respectively.

PES Measurements. The bare TiO₂ and aminosilane-modified TiO₂ samples were mounted in air and loaded into a UHV system for PES measurements. HR- and AR-XPS (monochromatic Al Kα excitation at 1486.3 eV, 300 W, pass energy of 20 eV) measurements of the pristine substrates were acquired using a Kratos Axis Ultra PES system with a base pressure of 2×10⁻⁹ Torr. For XPS throughout the vacuum co-evaporation experiments, CL spectra are taken at a takeoff angle of 0° using a non-monochromatic Mg Kα XPS source (1253.6 eV, 12 kV, 20 mA) and a Phoibos 100 hemispherical analyzer (pass energy of 10 eV). UPS measurements were taken with a monochromatic VUV 5000 microwave UV source (VG Scienta) using the He Iα emission line (21.22 eV) with a −8 V sample bias and an analyzer pass energy of 2 eV. The photoelectron BE scale was calibrated using the Fermi edge (0.00 eV) and Au 4f_{7/2} peak (84.00 eV) of a sputter-cleaned gold sample. No significant change in the BE or shape of the XPS CL or UPS VB/SECO spectra was observed for any of the samples during analysis with UV or X-ray irradiation.

Co-evaporation of MAI and PbI₂. The thermal co-evaporation of MAPbI₃/precursor films onto the TiO₂ contacts and subsequent PES characterization have been conducted over a two-week period. See, for example, Olthof, S. et al., in “Substrate-dependent electronic structure and film formation of MAPbI₃ perovskites,” Sci Rep, 2017, 7, 40267. Briefly, MAI and PbI₂ were evaporated from two separate quartz Knudsen cells in the growth chamber (base pressure in the mid 10⁻⁸ mbar range) at rates of 0.60 Å/s (ca. 120° C.) and 0.40 Å/s (ca. 300° C.), respectively, which were measured with individually-calibrated QCMs, at a pressure of ca. 4×10⁻⁴ mbar. After each deposition, the films were transferred without breaking vacuum to the preparation chamber (base pressure in the low 10⁻⁹ mbar range) and annealed at 70° C. for 1 hour. After cooling, the samples were transferred to the analysis chamber for PES measurements.

Results and Discussion

Defective TiO₂ and aminosilane-modified TiO₂ surfaces: Amorphous, compact TiO₂ contacts were deposited onto indium tin oxide (ITO) by chemical vapor deposition. The bare “TiO₂” sample was activated with oxygen plasma to remove surface-adsorbed contaminants. In order to passivate surface defects, APTES was reproducibly adsorbed to the activated TiO₂ surface in a dry nitrogen atmosphere from the vapor-phase, and subsequent treatment in 50 mM (pH=1.3) HCl (“APTES-HCl” sample) or 10 mM (pH=12.0) KOH (“APTES-KOH” sample) hydrolyzes unreacted ethoxy groups and changes the relative fraction of protonated amine (pKa˜10.5). It should be appreciated that other passivating agent disclosed herein can be used in place-of or as a combination to APTES.

The near-surface chemical composition of TiO₂, APTES-HCl and APTES-KOH samples was characterized with high-resolution, angle-resolved XPS (AR-XPS), which provided information on the relative depth distribution of atomic species and aminosilane orientation. Full AR-XPS characterization of bare and aminosilane-modified TiO₂ samples were obtained. The XPS probe depth (dₚ) decreased by about a factor of two for a 60° TOA, providing enhanced surface sensitivity compared to a more bulk-sensitive TOA of 0°. The bare TiO₂ O 1s CL spectrum was deconvoluted with four peaks attributed to lattice oxygen (Oₗₐₜ), surface hydroxyls (bridging, 2-coordinate —OH_{br,2c} and terminal, 1-coordinate —OH_{t,1c}) and adsorbed oxygen (O_{2(ads)}) species.

Absorption of a passivating agent disclosed herein, such as APTES, resulted in a significant increase in the high binding energy (BE) shoulder, which is ascribed to SiO bonds. The relative intensity of Oₗₐₜ decreases at 60° for all samples, indicating that Oₗₐₜ is located below the TiO₂ surface. The intensity of high BE 0 is species increased at 60° for all samples, signifying that these species are more prevalent at or above the TiO₂ surface.

AR-XPS N is spectra for bare and a passivating agent (e.g., APTES)-treated TiO₂ samples showed two, low-intensity N 1s species, which increased in intensity and maintained a similar ratio at 60°, on the bare TiO₂ sample are attributed to surface adsorbed N₂ near oxidized, 5-coordinate Ti_{5c}⁴⁺ (low BE) and reduced, 4-coordinate Ti_{4c}³⁺ surface species. As expected, a passivating agent adsorption resulted in a large increase in the N 1s CL signal, which was deconvoluted with a low BE (unprotonated) and high BE (protonated) amine species. Relative to as-deposited APTES, HCl and KOH treatment increased the fraction of protonated and unprotonated amines by ca. 5%, respectively. The fraction of protonated amine decreased by ca. 10% at 60° for all samples and indicates that the ammonium groups are located closer to the oxide surface when compared to amine groups.

The thickness of the APTES layer was estimated by determining the relative attenuation of the Ti 2p signal, yielding values of 3.5±0.3 Å for APTES-HCl and 4.4±0.2 Å for APTES-KOH. Compared to APTES-AD, these thickness values correspond to a 26±3% and 6±2% decrease in APTES coverage after HCl and KOH treatment, respectively. The general orientation of APTES molecules was determined by analyzing the change in N/Ti, Si/Ti and N/Si atomic ratio at a TOA of 60° relative to 0°. Relative to 0°, the N/Ti and Si/Ti ratio increased by ca. 70-80% and 120-130% at 60°, respectively. Conversely, the N/Si ratio decreased by ca. 20-30% and indicates that N atoms are closer to the TiO₂ surface than Si atoms. These results clearly demonstrate that APTES molecules are primarily oriented parallel to the TiO₂ surface due to strong interactions between the amine/ammonium group and TiO₂ surface species.

Oxidized Ti_{5c}⁴⁺ sites and reduced Ti_{4c}³⁺ species near oxygen vacancy (V_{O}) and titanium interstitial (Ti_{I}) defects are strong Lewis acids. Electron transfer from reduced defects to O_{2(ads)}, which is present for oxygen plasma-treated amorphous TiO₂ films, can lead to adsorbed superoxide (O₂⁻._{(ads)}) species. Compared to terminal hydroxyls (OH_{t,1c}; pKₐ≈7.8), protonated bridging oxygens (OH_{br,2c}; pKₐ≈5.0) are more acidic and abundant on the TiO₂ surface. Low coverages of N₂ (ads) species can also bind to Ti_{5c}⁴⁺ and Ti_{4c}³⁺ sites.

AR-XPS revealed that the passivating agent molecules are primarily oriented parallel to the TiO₂ surface with the amine group located below the Si atom due to hydrogen (e.g., H₂—NHO_{t,1c}), coordinate covalent (e.g., H₂N→Ti) and ionic (e.g., NH³⁺—O⁻) bonds with TiO₂ surface species. The reduced coverage for APTES-HCl samples may be due to protonation and desorption of non-covalently bound APTES molecules and/or hydrolysis of condensed SiOTi bonds, resulting in a higher density of unpassivated Ti sites and OH groups compared to APTES-KOH samples. AR-XPS results show that HCl and KOH treatment also results in adsorbed chloride (Cl⁻_{(ads)}) and potassium (K⁺_{(ads)}) species, which are respectively bound to Ti and O⁻ species.

Gas-phase MAI species during vacuum co-evaporation of MAPbI₃ precursors: During degradation of MAPbI₃ and sublimation of MAI in vacuum, MAI can dissociate into the parent compounds (equation (1a)) or has been reported to chemically transform into ammonia and methyl iodide (equation (1b)⁴²):

CH₃NH₃⁺I⁻₍ₛ₎ [symbol] CH₃NH_{2(g)}+HI_{(g)} (1a)

CH₃NH₃⁺I⁻₍ₛ₎ [symbol] NH_{3(g)}+CH₃I_{(g)} (1b)

MS results support equation (1a) when MAI was sublimed from quartz Knudsen cells. These findings suggest that MAI is incorporated into vacuum-processed MAPbI₃ films by surface adsorption (equation (2a)) and subsequent coupling (equation (2b)) of methylamine and HI at Ti or Pb Lewis acid sites. MAI coupling competes with surface-catalyzed dissociation reactions that can lead to adsorbed methyl iodide and ammonia species (equation 2(c)):

CH₃NH_{2(g)}+HI_{(g)} [symbol] CH₃NH_{2(ads)}+HI_{(ads)} (2a)

CH₃NH_{2(ads)}+HI_{(ads)} [symbol] CH₃NH₃⁺I⁻_{(ads)} (2b)

CH₃NH_{2(ads})+HI_{(ads)} [symbol] CH₃I_{(ads)}+NH_{3(ads)} (2c)

Growth of MAPbI₃ films on TiO₂ contacts: MAI/PbI₂ precursors were incrementally co-evaporated with film thicknesses between 2 and 200 nm onto TiO₂, APTES-HCl and APTES-KOH samples. The term “nominal thickness” indicates that the film thickness may deviate from quartz crystal microbalance measurements.

The thickness-dependent attenuation of all observable substrate-specific Ti 2p and O 1s XPS CL signals provided insight into the film growth mechanism. The measured inelastic free path (λₙ) of the Ti 2p_{3/2} and total O 1s (O 1sₜₒₜ) signal was compared with the expected λₙ for layer-by-layer (LBL) film growth. Agreement between the measured and expected λₙ values for the APTES-modified TiO₂ contacts indicates conformal film growth, and a ca. 3× increase in the measured λₙ on the bare TiO₂ surface suggests island film growth.

Temperature programmed desorption (TPD) studies have shown that dipolar Lewis bases, which are associated with MAI reaction products (e.g., methylamine and methyl iodide), primarily bind to TiO₂ surfaces at Ti Lewis acid sites and result in non-polar, methyl-terminated surfaces, which is believed to lead to dewetting of polar PbI₂ and island growth for precursor films on bare TiO₂. The multifunctional APTES molecules mitigate full surface occupation by methyl-terminated molecules and afford a sufficiently polar and low free energy TiO₂ surface for conformal film growth.

Surface reactions between MAPbI₃ precursors and TiO₂: Hydroxyl-mediated precursor decomposition was assessed by analyzing the thickness-dependent OH_{t,1c}/OH_{br,2c} ratio for the buried TiO₂ contacts. In general, this ratio asymptotically approached an equilibrium state (ratio=1) with increasing film thickness.

These chemically unique hydroxyl groups can participate in “dark” proton-coupled redox chemistry:

Ti—OH_{t,1c}³⁺+H⁺+e⁻ [symbol] Ti³⁺+H₂O; E≈−0.06 V vs NHE (3a)

Ti—OH_{br,2c}+ [symbol] O_{br,2c}+H⁺; pKₐ₁≈5.0 (3b)

Ti—OH_{t,1c} [symbol] TiO_{t,1c}⁻+H⁺; pKₐ₂=7.8 (3c)

Ti_{5c}⁴⁺ sites can be reduced to Ti_{4c}³⁺ via inner-sphere electron transfer from a surface-adsorbed electron donor, in the presence of protons to evolve water (equation (3a)). The availability of surface protons in vacuo depends on the concentration of acidic bridging and basic terminal hydroxyls, which is governed at least in part by TiO₂ acid/base chemistry in equation (3b) and (3c), respectively, and the surface concentration of HI and methylamine.

It has been reported that reactions between terminal hydroxyls and methyl iodide can produce bridging hydroxyls, adsorbed iodide and methoxy species, which is proposed by the present inventors to occurs via equation (4a). Equation (4b) is proposed here to explain desorption of dimethyl ether after methoxy coupling.

2CH₃I_{(ads)}+2OH_{t,1c}+2O_{br,2c} [symbol] 2CH₃O_{(ads)}+2OH_{br,2c}+2I⁻_{(ads)} (4a)

2CH₃O_{(ads)}+OH_{br,2c}→(H₃C)₂O_{(g)}+O_{br,2c}+OH_{t,1c} (4b)

The net reaction between OH_{4,1c} and methyl iodide yields OH_{br,2c} and reduced Ti_{4c}³⁺ products provides a mechanism for hydroxyl-mediated decomposition of MA-related species. Therefore, equilibration of the OH_{t,1c} (reactant)/OH_{br,2c} (product) ratio indicates that surface-catalyzed dissociation and proton-coupled redox reactions facilitate electronic equilibration between the TiO₂ contact and MAPbI₃ film.

MAPbI₃ nucleation and chemical/energetic environment: Thickness-dependent stoichiometries, which are reported as the ratio w.r.t. Pb and extracted from XPS CL spectra showed that TiO₂ surface chemistry drastically affects the passivation/MAPbI₃ layer composition. The “nucleation thickness,” which is when the measured atomic ratios reach the MAPbI₃ stoichiometry, was 2-3× thinner for aminosilane-modified (ca. 5 nm for APTES-HCl and 8 nm for APTES-KOH) compared to the unmodified (ca. 15 nm) TiO₂ contact.

In another experiment, a nitrogen-deficient passivation layer was formed prior to MAPbI₃ nucleation on the three TiO₂ contacts. This finding supports dissociative adsorption of MAI decomposition products (equation (2a) and (2c)), followed by desorption of weakly adsorbed species such as CH₃NH₂ (reverse of equation (2a)) and NH₃. Compared to the sharp increase in the N/Pb ratio on the bare TiO₂ contact that coincides with nucleation and indicates a step-like compositional transition, the N/Pb ratio steadily increased between 2 nm and 10 nm on the APTES-modified TiO₂ contacts and indicated a gradient in the relative methylammonium concentration within the passivation and perovskite layer.

Prior to measuring an observable N is signal (<10 nm), the I/Pb ratio on the TiO₂ contact varied between ca. 2 and 2.5 implying that the passivation layer was composed of a range of disordered iodide species that were stabilized by uncoordinated Ti surface sites. The I/Pb ratio on the APTES-HCl surface was only slightly below 3 prior to nucleation when compared to the more PbI₂-like I/Pb ratio on the APTES-KOH contact; this comparison suggests that iodide anions are stabilized on the APTES-HCl surface by a higher fraction of uncoordinated Ti sites, which result from desorption of APTES molecules during HCl treatment. Disordered iodide species can migrate during PV operation and have been associated with J-V hysteresis and poor stabilized efficiency.

A small relative concentration of metallic Pb⁰ is related to oxidation of iodide anions (equation (5)):

2I⁻_{(ads)}+Pb²⁺_{(ads)} [symbol] I_{2(g)}+Pb⁰_{(ads)} (5)

The Pb⁰/Pb²⁺ ratio is typically higher for the precursor/MAPbI₃ films on the less-reactive, APTES-treated TiO₂ surfaces and suggests that excess, unreacted MAI on the passivation/perovskite layer pushes equation (5) toward formation of Pb⁰.

The near-surface chemical bonding and energetic environment for the buried TiO₂ contacts and MAPbI₃ films during precursor/MAPbI₃ film growth are evaluated by analyzing the TiO₂- and PAL-specific BE shifts. For each TiO₂ substrate, the CL peaks move to higher BE and equilibrate at an O 1sₗₐₜ and Ti 2p_{3/2} BE of ca. 530.5 eV and 459.1 eV, respectively. Positive BE shifts indicate electrochemical reduction of the TiO₂ contact and add further support for the reaction mechanisms associated with equation (3a), (4a) and (4b). Equilibration of the CL shifts at the same BE for all three TiO₂ contacts suggests pinning of the conduction band minimum energy (E_{CBM}) just above E_{F} (see below).

In contrast to substrate peaks, BE shifts for precursor-specific CL spectra are determined relative to the “bulk” MAPbI₃ film (200 nm). The Pb 4f_{7/2} and I 3d_{5/2} CL peaks shift to lower BE and equilibrate at bulk-like BEs for the ca. 200 nm thick film on all three contacts. For the TiO₂ and APTES-HCl contacts, the negative deviation of the Pb 4f_{7/2} and I 3d_{5/2} BE shift w.r.t. the bulk indicates the presence of a charge transport barrier due to enhanced concentrations of interfacial iodide. Conversely, an upward shift in Pb 4f_{7/2} and I 3d_{5/2} BE during film growth on the APTES-KOH contact indicates ideal band bending for charge transport within the passivation layer and MAPbI₃ film. Orthogonal N 1s BE shifts prior to nucleation suggest enhanced polarization due to a more iodide-rich passivation layer.

In the gas-phase, MAI primarily dissociates into methylamine and hydroiodic acid, which are strong Lewis bases that primarily adsorb at Ti_{5c}⁴⁺ and Ti_{4c}³⁺ Lewis acid sites. Surface-catalyzed dissociation reactions can produce surface-adsorbed ammonia, methyl iodide and methoxy species. Redox reactions between MAI decomposition products and surface hydroxyls, along with desorption of adsorbed superoxide (equation (6)), result in reduced Ti_{4c}³⁺ sites and loss of volatile products. Without being bound by any theory, it is believed that additional reactions and products are possible and depend on the PAL composition and processing conditions, as well as TiO₂ surface chemistry.

Since deposition of MAI is believed to be omnidirectional, it is believed that bare TiO₂ regions are saturated with methyl-terminated molecules prior to PbI₂ deposition, and multifunctional APTES molecules result in a more polar interface. These differences in surface free energy and reactivity result in island film growth on bare TiO₂ and conformal growth on APTES-modified TiO₂ contacts, where volatile reactants and products diffuse through pinholes in the film until equilibrium is reached between the TiO₂ contact and passivation/MAPbI₃ layer. Passivation of reactive surface sites with a passivating agent (e.g., APTES) led to larger, more homogeneous MAPbI₃ crystallites and compositionally-graded, thinner passivation layers.

Thickness-dependent XPS and UPS provide valuable insight related to charge transport within the MAPbI₃ film, electron collection at the TiO₂ contact and possible charge recombination pathways that impact the performance and operation of PV devices.

Again without being bound by any theory, it is believed that the TiO₂ electronic structure results from equilibration of the interfacial and bulk energetics, which is assumed to result in flat band conditions for all three contacts. The close proximity between the CBM and Fermi level leads to n-type doping at the TiO₂ interface, which is accompanied by a reappearance of a localized V_{O}/Ti_{4c}³⁺ gap state (GSᵥₒ) at ca. 1.2 eV below E_{F}. These gap states improve the photoconductivity of TiO₂ and have led to enhanced charge extraction, performance and stability in PV devices.

An abrupt decrease in E_{VBM} coincides with MAPbI₃ nucleation on the bare TiO₂ substrate. A constant E_{VBM} between the passivation layer and the film bulk indicates the absence of band bending on the bare TiO₂ contact (ΔE_{VBM,TiO2}=0 eV), suggesting that the majority of the driving force responsible for charge redistribution and, thus, contact equilibration has been lost to sluggish nucleation kinetics on the more reactive TiO₂ contact. A similar degree of band bending (ΔE_{VBM,APTES-HCl}=0.20 eV and ΔE_{VBM,APTES-KOH}=0.24 eV) was observed for the films on the APTES-treated TiO₂ contacts. These shifts asymptote at a nominal thickness of 50 nm, which approximates the width of the accumulation layer. Strong qualitative agreement between the thickness-dependent N/Pb ratio and E_{V}BM shows that band bending is linked to the composition of the passivation layer, where decreased surface reactivity improves electronic coupling between the APTES-modified TiO₂ contacts and the MAPbI₃ active layer.

E_{CBM} is estimated for the MAPbI₃ layer by addition of the optical gap (E_{g,opt}≈1.6 eV) to E_{VBM}. For thicknesses that show significant N/Pb deficiencies within the passivation layer, E_{CBM} is estimated by addition of the PbI₂ optical gap (E_{g,opt}≈2.2 eV) to E_{VBM}. This PbI₂-rich interface layer introduces a ca. 0.6 eV energy barrier for electron transfer from MAPbI₃ to the TiO₂ contact. Without being bound by any theory, it is believed that thick and MA-deficient passivation layers, which result from uncontrolled interface chemistry, are responsible for the previously reported CB mismatch between TiO₂ contacts and MAPbI₃.

The difference between changes in the bulk work function (ΔΦ) and band bending across the interface yields the total interface dipole (eDₜₒₜ, equation (7)):

eDₜₒₜ=ΔΦ−ΔE_{VBM} (7)

The bare TiO₂/MAPbI₃ heterojunction yields the largest total interface dipole (eD_{TiO2(tot)}=0.40 eV), which compensates for the absence of band bending in the active layer. Due to enhanced band bending and a smaller bulk work function, the smallest interface dipole is found on the APTES-KOH contact (eD_{APTES-KOH(tot)}=0.14 eV), and the interface dipole is slightly larger for the APTES-KOH/MAPbI₃ heterojunction (eD_{APTES-HCl(tot)}=0.20 eV). Therefore, smaller interface dipoles indicate decreased contact reactivity and improved interfacial energetics.

As shown herein, passivation of reactive TiO₂ surface sites with APTES SAMs leads to thinner and compositionally-graded passivation layers, which improve interfacial energetics that control the efficiency of charge transport and collection. Therefore, optimization of heterojunctions between metal oxide electrode and hybrid organic-inorganic perovskite for PV applications is enabled by understanding and controlling TiO₂ surface composition and chemistry.

As disclosed herein, surface-catalyzed and proton-coupled redox reactions between MAI-related species and undercoordinated Ti sites and OH groups lead to the formation of methylammonium-deficient, iodide-rich and electron-blocking interface passivation layers, which have been linked to poor performance and stability of solar cell devices. By using a passivating agent disclosed herein, the present inventors have demonstrated that such a treatment results in strong bonding interactions between the amine/ammonium terminal group of low-cost and scalable APTES SAMs passivate reactive TiO₂ surface sites and significantly mitigate the formation of deleterious interface passivation layers. In addition, the present inventors have discovered that reduced reactivity for APTES-modified TiO₂ surfaces promotes enhanced electronic coupling between the MAPbI₃ and TiO₂ contact, resulting in reduced interface dipoles and improved band bending that facilitates charge transport and extraction.

As further demonstrated herein, passivation of reactive TiO₂ surface sites with a passivating agent enables the ability to control the interfacial chemical composition and electronic structure of the PAL, which significantly influence the stability and performance of PAL/TiO₂ heterojunctions in optoelectronic device platforms.

The foregoing discussion of the invention has been presented for purposes of illustration and description. The foregoing is not intended to limit the invention to the form or forms disclosed herein. Although the description of the invention has included description of one or more embodiments and certain variations and modifications, other variations and modifications are within the scope of the invention, e.g., as may be within the skill and knowledge of those in the art, after understanding the present disclosure. It is intended to obtain rights which include alternative embodiments to the extent permitted, including alternate, interchangeable and/or equivalent structures, functions, ranges or steps to those claimed, whether or not such alternate, interchangeable and/or equivalent structures, functions, ranges or steps are disclosed herein, and without intending to publicly dedicate any patentable subject matter. All references cited herein are incorporated by reference in their entirety.

1-21. (canceled)

22. A composition comprising: (i) a metal oxide electrode comprising a modified surface, wherein said modified surface comprises a passivating agent that is attached to a surface of said metal oxide electrode, and (iii) a hybrid organic-inorganic perovskite active layer in contact with said modified surface of said metal oxide electrode.

23. The composition of claim 22, wherein the presence of said passivating agent reduces the amount of defects present in the interface between said metal oxide electrode and said hybrid organic-inorganic perovskite active layer.

24. The composition of claim 22, wherein said composition comprises a monolayer of said passivating agent on said metal oxide surface.

25. The composition of claim 22, wherein said passivating agent comprises a multifunctional silane compound.

26. The composition of claim 22, wherein said passivating agent is a bifunctional silane compound.

27. The composition of claim 22, wherein said passivating agent is of the formula:
A-R—B, wherein A is a silane functional group, R is a linker having from about 3 to 20 atoms in a chain between A and B; and B comprises an amino group, mercapto, halide, sulfobetane, carboxybetane, or a combination thereof; or R and B together form optionally substituted para-aminophenyl, or pyridine moiety.

28. The composition of claim 27, wherein A is of the formula (R¹)₃—Si—, wherein each of R₁ is independently selected from the group consisting of alkoxide and halide.

29. The composition of claim 27, wherein B comprises —NR^{a}₂; —NR^{a}—[C₁₋₆ alkylene]-NR^{a}₂; —SH; —X; —N⁺(R^{a})₂—[C₁₋₆ alkylene]-SO₃⁻; and —N⁺(R^{a})₂—[C₁₋₆ alkylene]-CO₂⁻, wherein
each R^{a} is independently hydrogen or C₁₋₁₀ alkyl; and
X is halide.

30. The composition of claim 22, wherein said passivating agent is selected from the group consisting of a compound of the formula: 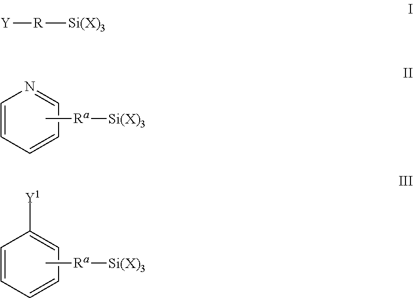
and a mixture thereof wherein
Y and Y¹ is —NR¹R², —SH, halide, or 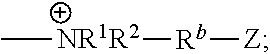
each of R¹ and R² is independently H or C₁₋₁₀ alkyl;
R^{a} is absent or C₁₋₁₀ alkylene;
R^{b} is C₂₋₁₀ alkylene;
each X is independently halide or —OR¹; and
Z is —SO₃⁻ or —CO₂⁻.

31. The composition of claim 22, wherein said metal oxide layer comprises titanium oxide (TiO₂), indium-tin oxide, tin oxide (SnO₂), nickel oxide (NiO), zinc oxide (ZnO), aluminum-doped zinc oxide (AZO), indium-zinc oxide (IZO), a ternary or quaternary metal oxide, or gallium-zinc-indium oxide (GIZO).

32. The composition of claim 22, wherein said hybrid perovskite comprises methylammonium lead trihalide (MAPbX₃), methylammonium tin trihalide (MASnX₃), formamidinium lead or tin trihalide, cesium lead or tin trihalide, or combinations of lead (or tin) as the central metal cation, and additional cations including cesium, rubidium, bismuth, methylamine, ethylamine, formamidinium-amine and related singly charged metal and organic cations.

33. An electronic device comprising a composition of claim 22.

34. The electronic device of claim 33, wherein said device comprises a photovoltaic cell, a light-emitting diode, or a field-effect transistor.

35. A method for increasing stability or photovoltaic power conversion efficiency in an electronic component composition comprising a hybrid perovskite layer and a metal oxide electrode, said method comprising:
passivating a surface of said metal oxide electrode with a passivating agent to produce a passivated electrode surface, wherein said passivated electrode surface comprises a thin layer of said passivating agent; and
contacting said passivated electrode surface with a hybrid perovskite precursor to form said electronic component having said thin layer of said passivating agent between said metal oxide electrode and said hybrid perovskite layer,
wherein the presence of said thin layer of said passivating agent increases stability and/or photovoltaic power conversion efficiency of said electronic component compared to the same electronic component in the absence of said passivating agent.

36. The method of claim 35, wherein said passivated electrode surface comprises a self-assembled monolayer of said passivating agent.

37. The method of claim 35, wherein said passivating agent reduces the total number of reactive sites on the surface of said metal oxide electrode.

38. The method of claim 35, wherein said passivation of said metal oxide layer comprises a chemical vapor deposition process or a solution-based process.

39. A method for reducing hysteresis in an electronic component comprising a hybrid perovskite layer and a metal oxide layer, said method comprising providing a thin layer of a passivating agent between the interface of said metal oxide layer and said hybrid perovskite layer such that the presence of said thin layer of passivating agent reduces hysteresis in said electronic component compared to the same electronic component in the absence of said thin layer of passivating agent.

40. The method of claim 39, wherein said thin layer of passivating agent is provided between the interface of said metal oxide layer and said hybrid perovskite layer by steps comprising:
contacting a surface of said metal oxide layer with a passivating agent to produce a passivated electrode surface, wherein said passivated electrode surface comprises a thin layer of said passivating agent on the surface of said metal oxide; and
forming a hybrid perovskite layer on said passivated electrode surface to produce said electronic component having a passivation layer between said metal oxide layer and said hybrid perovskite layer,
wherein the presence of said passivation layer decreases hysteresis of said electronic component compared to the same electronic component in the absence of said passivation layer.

41. The method of claim 40, wherein said step of providing said step of contacting said metal oxide surface with said passivating agent comprises a chemical vapor deposition process or a solution-based process.
